(19) United States
(12) Patent Application Publication
(10) Pub. No.: US 2010/0243618 A1
(43) Pub. Date: Sep. 30, 2010

(54) TEMPERATURE CONTROL METHOD FOR HEATING APPARATUS

(75) Inventors: Masami Shibagaki, Fuchu-shi (JP); Kaori Mashimo, Kawasaki-shi (JP); Hiroshi Doi, Chofu-shi (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/726,558

(22) Filed: Mar. 18, 2010

(30) Foreign Application Priority Data
Mar. 27, 2009 (JP) 2009-078192
Mar. 4, 2010 (JP) 2010-048233

(51) Int. Cl. H01L 21/324; H01J 37/20

(52) U.S. Cl. 219/121.23; 219/121.35; 219/448.12

(57) ABSTRACT

A temperature control method for a heating apparatus including a chamber which can be evacuated and has a conductive portion, a filament which is positioned in the chamber, a first power supply which supplies a current to the filament, a second power supply which applies, to the filament, a voltage for acceleration to the chamber, an ammeter which measures a current of the filament, and a voltmeter which measures the acceleration voltage, the method comprises a first step of evacuating an interior of the chamber; a second step of supplying the filament current from the first power supply to the filament after the first step; a third step of applying the acceleration voltage to the filament after the second step; and a fourth step of controlling the acceleration voltage to keep a surface temperature of the chamber to be lower than a temperature of the filament after the third step while keeping constant the filament current from the first power supply.

### BACKGROUND OF THE INVENTION

1. Field of the Invention

The present invention relates to a temperature control method for a heating apparatus using an electron impact heating method for heating a semiconductor substrate to a high temperature in a vacuum in the manufacture of a semiconductor device.

2. Description of the Related Art

The manufacture of a semiconductor device requires a process of heating a semiconductor substrate quickly. In general, a temperature of 1,600° C. or higher is necessary particularly in activation annealing treatment for a wide bandgap semiconductor represented by silicon carbide (SiC) (see reference 1: T. Kimoto, N. Inoue and H. Matsunami: Phys. Stat. Sol. (a) Vol. 162 (1997), p. 263).

In activation annealing treatment, to ensure high semiconductor device reliability it is very important to electrically activate a doped impurity by 100% and restore perfect crystals. To make activation annealing treatment usable in industrial requirements, heating treatment must be completed within a short time in order to increase the throughput of the processing apparatus. This requires a treatment at an ultra-high temperature of 2,000° C. or higher, which exceeds temperatures conventionally used in practice.

As an apparatus capable of such a treatment, there is known a substrate heating apparatus using an electron impact heating system. A vacuum chamber in this heating apparatus includes a carbon heating chamber which can be independently evacuated. The chamber incorporates a heating device (heater) having a built-in filament (e.g., see Japanese Patent No. 3866685). In the substrate heating apparatus, the filament is heated and charged negatively with respect to the heating chamber, accelerating thermoelectrons toward the heating chamber. The accelerated thermoelectrons collide against the heating chamber, thereby heating the heating plate.

Japanese Patent No. 3866685 also discloses a temperature control method for an electron impact heater. According to this temperature control method, when the temperature of the heating plate rises, an emission current regulator measures an emission current flowing through a path between the filament and the heating plate. At the same time, a power regulator controls the emission current to have a preset value. After the heating plate reaches a set temperature, the power regulator controls the heating plate at a preset temperature while a temperature regulator measures the heating plate temperature.

Table 1 below shows the relationship between the heater temperature and the filament current value in the use of a 0.8-mmφ tungsten filament when it stabilizes at each heater set temperature in case that the temperature control method disclosed in Japanese Patent No. 3866685 is adopted. Table 1 reveals that as the heater temperature rises, the filament itself is heated by the heating chamber and the emission current value isapt to be easily increased, so the filament current value is decreased.

TABLE 1

| Heater Temperature | Filament Current Value |
|---|---|
| 1,700° C. | 26.0 A |
| 1,800° C. | 24.3 A |
| 1,900° C. | 22.2 A |
| 2,000° C. | 19.7 A |

Reference 2 (Irving Langmuir, Phys. Rev., 1916, pp. 302-330) discloses the relationship shown in Table 2 between the filament current value and the filament temperature for a 0.8-mmφ tungsten filament. As is apparent from Table 2, decreasing the filament current value results in a lower filament temperature.

TABLE 2

| Filament Current Value | Filament Temperature |
|---|---|
| 26.0 A | 1,830° C. |
| 24.3 A | 1,746° C. |
| 22.2 A | 1,642° C. |
| 19.7 A | 1,520° C. |

Based on Tables 1 and 2, Table 3 shows the relationship between the heater temperature and the filament temperature when the heater temperature stabilizes. Table 3 reveals that, for example, the filament temperature is 1,830° C. at a heater temperature of 1,700° C. and the filament temperature is higher than the heater temperature.

TABLE 3

| Heater Temperature | Filament Temperature |
|---|---|
| 1,700° C. | 1,830° C. |
| 1,800° C. | 1,746° C. |
| 1,900° C. | 1,642° C. |
| 2,000° C. | 1,520° C. |

That is, when the heater temperature is low (e.g., around 1,700° C.), so that the thermoelectron emission amount is decreased, that is, the emission current value is decreased, the filament current value is decreased, and heat is dissipated from the filament toward the heater by radiation, thereby decreasing the filament temperature and controlling the emission current value.

As described above, as the heater temperature rises, the filament is also heated by the heating chamber and the emission current value is apt to be easily increased, so the filament current value is decreased. At a heater temperature of 1,800° C., the filament temperature falls below that of the heater temperature.

Further, when the heater temperature rises to 2,000° C., the filament temperature becomes much lower than the heater temperature. Even if control of the heater temperature is attempted via suppression of the emission current value, the filament is heated by heat radiated from the heating chamber, the emission current value can no longer be controlled, and the emission current thermally runs away.

As described above, the temperature control method in Japanese Patent No. 3866685 suffers a failure to stably control the heater temperature due to the runaway of the emission current at heater temperatures of 2,000° C. or higher.

### SUMMARY OF THE INVENTION

The present invention has been made to solve the above problems, and has as its object to provide a temperature control method of a heating apparatus capable of performing stable temperature control in an electron impact heating method.

More specifically, it is an object of the present invention to provide a temperature control method of a heating apparatus capable of avoiding, even in a high temperature region of 2,000° C. or higher, a state in which the heater temperature becomes uncontrollable due to the runaway of an emission current.

In order to solve the aforementioned problems, the present invention provides a temperature control method for a heating apparatus including a chamber which can be evacuated and has a conductive portion, a filament which is positioned in the chamber, a first power supply which supplies a current to the filament, a second power supply which applies, to the filament, a voltage for acceleration to the chamber, an ammeter which measures a current of the filament, and a voltmeter which measures the acceleration voltage, the method comprising: a first step of evacuating an interior of the chamber; a second step of supplying the filament current from the first power supply to the filament after the first step; a third step of applying the acceleration voltage to the filament after the second step; and a fourth step of controlling the acceleration voltage to keep a surface temperature of the chamber to be lower than a temperature of the filament after the third step while keeping constant the filament current from the first power supply.

According to the present invention, the filament temperature is kept higher than the surface temperature of a heating chamber in the electron impact heating system. Even at an ultrahigh temperature of 2,000° C. or higher, a state in which the heater temperature becomes uncontrollable due to the runaway of an emission current can be avoided. Therefore, stable temperature control can be performed in the electron impact heating system.

Further features of the present invention will become apparent from the following description of exemplary embodiments with reference to the attached drawings.

### BRIEF DESCRIPTION OF THE DRAWINGS

FIG. 1 is a sectional view schematically showing the overall arrangement of an electron impact heating apparatus according to one embodiment of the present invention;

FIG. 2 is a schematic view showing the control system of the electron impact heating apparatus according to the embodiment;

FIG. 3 is a graph showing the temperature dependence of the activation ratio in an SiC p-well;

FIG. 4 is an explanatory view showing step 1 of a temperature control sequence in a temperature control method according to the embodiment;

FIG. 5 is an explanatory view showing step 2 of the temperature control sequence in the temperature control method according to the embodiment;

FIG. 6 is an explanatory view showing step 3 of the temperature control sequence in the temperature control method according to the embodiment;

FIG. 7 is an explanatory view showing step 4 of the temperature control sequence in the temperature control method according to the embodiment;

FIG. 8 is a graph showing a temperature rise curve when the heater temperature is held at 2,050° C. for 1 minute; and

FIG. 9 is a graph showing the relationship between the activation ratio and treatment temperature of the sample.

### DESCRIPTION OF THE EMBODIMENTS

A preferred embodiment of the present invention will now be described with reference to the accompanying drawings. However, the present invention is not limited to the following embodiment.

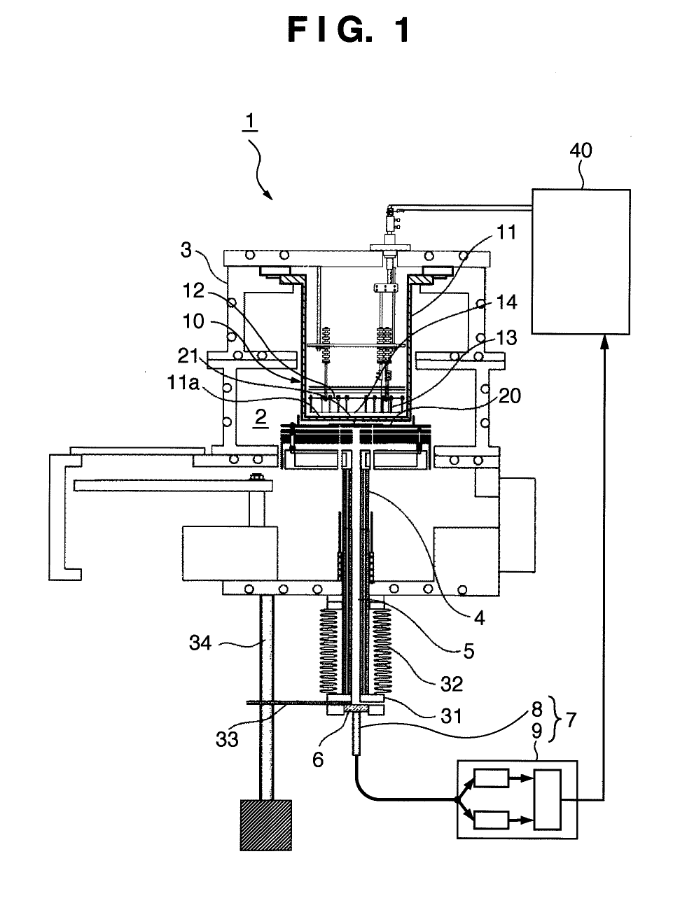

A substrate heating apparatus using an electron impact heating system (to be referred to as an “electron impact heating apparatus”) according to the embodiment of the present invention will now be explained with reference to FIG. 1. FIG. 1 is a sectional view schematically showing the overall arrangement of the electron impact heating apparatus according to the embodiment.

As shown in FIG. 1, an electron impact heating apparatus 1 of the embodiment includes a vacuum container 3 which partitions and forms a region for heating a treating substrate 21 and can be evacuated. The vacuum container 3 incorporates a heater 10 having a built-in filament 14.

The heater 10 includes a cylindrical heating chamber 11 having one end closed, and a filament base 12, columns 13, and the filament 14 which are stored in the heating chamber 11.

The filament 14 is stretched by the 2-mmφ tantalum columns 13 which stand on the filament base 12 made of, for example, a carbon fiber reinforced composite material (to be referred to as a “CC composite”), thereby the filament 14 is arranged to be almost parallel to a closed end face (heating plate) 11a of the heating chamber 11.

The filament 14 employs, for example, a tungsten-rhenium wire 0.8 mm in diameter and 900 mm in length.

The heating chamber 11 is formed from a conductor. More specifically, the base is made of graphite which is a material resistant to thermal stress. Either the outer or inner surface of the heating chamber 11 is coated with, for example, pyrolitic carbon to reduce emission gas. When reactive gas is used, tantalum carbide (TaC) is also usable as the coating material, instead of pyrolitic carbon. The heating chamber 11 is connected to an evacuation mechanism (not shown), and its interior can be evacuated independently of the vacuum container 3.

A wafer stage 20 made of a CC composite is arranged to face the heating plate 11a on the closed end face of the heating chamber 11. A treating substrate (wafer) 21 is set on the wafer stage 20 to face the heater 10. The embodiment employs, for example, a silicon carbide (SiC) wafer as the treating substrate 21.

A cylindrical column 4 supports the wafer stage 20, and a two-color radiation thermometer 7 is connected to the end of a through hole 5 of the column 4 via a quartz viewing port 6. The viewing port 6 closes the vacuum space to partition the vacuum space from the atmosphere. The radiation from the wafer stage 20 reaches the two-color radiation thermometer 7 via the viewing port 6.

The two-color radiation thermometer 7 includes, for example, a condenser 8 and detector 9. The two-color radiation thermometer 7 measures the temperature of the heater 10 indirectly via the wafer stage 20 made of a CC composite. Note that the temperature of the heating apparatus 1 may be measured by directly measuring that of the heater 10, or by, for example, forming a hole in the wafer stage 20 and indirectly measuring the temperature of the wafer 21 arranged to face the heater 10.

A support plate 31 is fixed to the lower end of the column 4, and a bellows 32 is interposed between the support plate 31 and the vacuum container 3. An extending piece 33 having an insertion hole (not shown) is fixed to the support plate 31, and a guide rod 34 is inserted in the insertion hole of the extending piece 33. The extending piece 33 is movable along the guide rod 34.

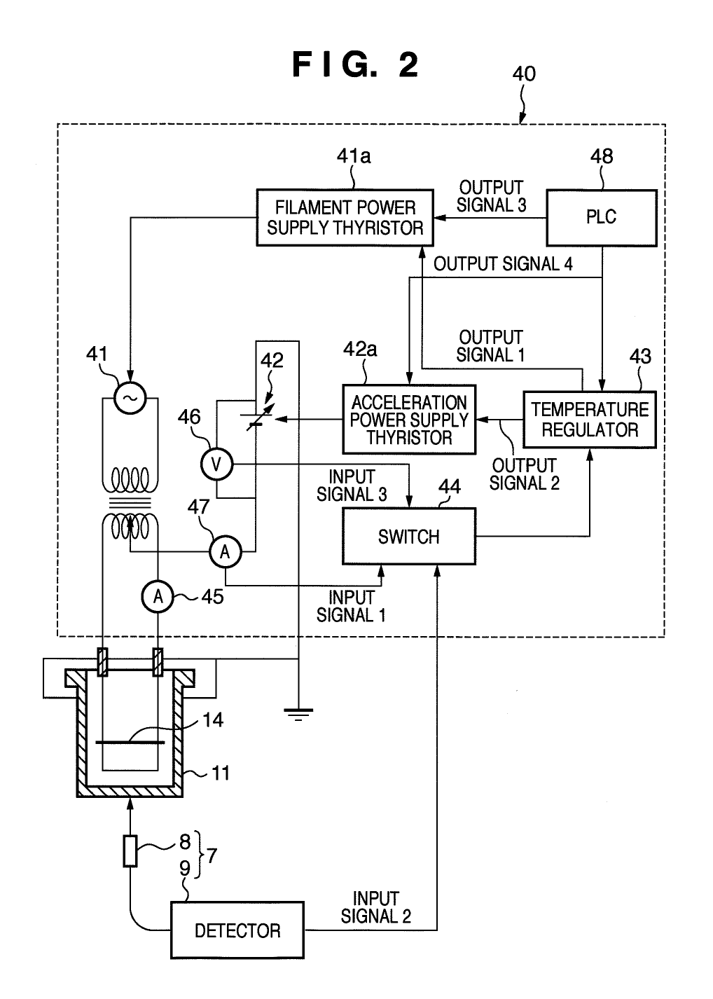

The arrangement of a control system in the electron impact heating apparatus according to the embodiment will be explained with reference to FIG. 2. FIG. 2 is a schematic view showing the control system of the electron impact heating apparatus according to the embodiment.

As shown in FIG. 2, a control system 40 of the embodiment includes a filament power supply 41, acceleration power supply 42, temperature regulator 43, switch 44, and PLC (Programmable Logic Controller) 48. The control system 40 receives a temperature measurement value (input signal 2) from the two-color radiation thermometer 7.

The filament power supply 41 is an AC power supply which supplies power for heating the filament 14, and can apply power variably up to, for example, 50 A. A filament ammeter 45 is connected to the connection circuit of the filament 14 to measure the current value of the filament 14.

The acceleration power supply 42 is a DC power supply which applies an acceleration voltage between the grounded heating chamber 11 and the filament 14. The acceleration power supply 42 can apply the acceleration voltage to the filament 14 variably from, for example, 0 V to −3.0 kV. The connection circuit of the acceleration power supply 42 is connected to an acceleration voltmeter 46 which measures an acceleration voltage, and an emission ammeter 47 which measures an emission current value.

The switch 44 is connected to the temperature regulator 43. The temperature regulator and switch may be integrated like, for example, SDC-46A available from Yamatake Corporation. The temperature regulator 43 receives input signal 1 from the emission ammeter 47 via the switch 44 and input signal 2 from the two-color radiation thermometer 7 via the switch 44, input signal 3 from the acceleration voltmeter 46 via the switch 44 Also, the temperature regulator 43 outputs output signal 1 to the filament power supply 41 via filament power supply thyristor 41a and output signal 2 to the acceleration power supply 42 via acceleration power supply thyristor 42a.

The PLC 48 outputs output signal 3 which is to be output to the filament power supply 41 via a thyristor 41a of the filament power supply 41 and indicates a current value. The PLC 48 can also output signal 4 which is to be output to the acceleration power supply 42 via a thyristor 42a of the acceleration power supply 42 and indicates an acceleration voltage value.

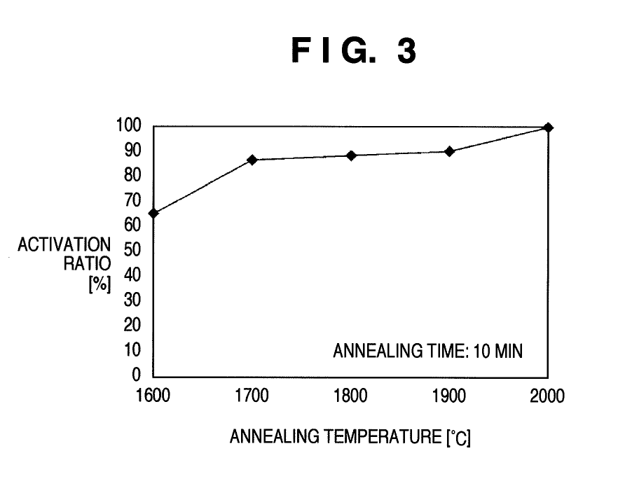

The temperature control method according to the embodiment of the present invention will be explained with reference from FIGS. 3 to 6 together with the operation of the electron impact heating apparatus 1 having the foregoing arrangement.

To operate the heater 10 of the electron impact heating apparatus 1, the filament power supply 41 supplies power to the filament 14. The DC acceleration power supply 42 negatively biases the filament 14. In contrast, the heating chamber 11 is at least partly made of, for example, a conductor such as carbon and is grounded. The overall structure of the heating chamber may be made of the conductor.

When the filament 14 is charged negatively with respect to the heating chamber 11 and a voltage for accelerating thermoelectrons toward the heating chamber is applied, thermoelectrons generated by the filament 14 are accelerated toward the heating chamber 11. The accelerated thermoelectrons collide against the heating chamber 11, heating it. The SiC wafer 21 arranged to face the heating plate 11a is heated by heat radiated from the heating plate 11a at the closed end of the heated heating chamber 11.

In activation annealing for a semiconductor substrate, to ensure high semiconductor device reliability, it is very important to electrically activate an implanted impurity by 100% and restore perfect crystals. From industrial requirements, it is also essential to shorten the treatment time of activation annealing.

As shown in FIG. 3, the present inventors have found out that 10-minute annealing at a high temperature of 2,000° C. could electrically activate an implanted impurity by 100% and completely eliminate crystal defects. FIG. 3 is a graph showing the temperature dependence of the activation ratio in an SiC p-well upon annealing for 10 minutes. In FIG. 3, an aluminum-implanted sample was used to form an SiC MOSFET (Metal Oxide Semiconductor Field Effect Transistor) p-well in the electron impact heating method.

The conventional research on annealing of forming an n⁺-contact region by implanted nitrogen into SiC has revealed that a higher activation ratio in SiC activation annealing could be obtained by heating at a higher temperature in a shorter time (see reference: M. Shibagaki, Y. Kurematsu, F. Watanabe, S. Haga, K. Miura, T. Suzuki and M. Satoh: Mater. Sci Forum Vol. 483-485, p. 609 (2005)).

From this, according to the temperature control method of the present embodiment, a semiconductor substrate undergoes activation annealing at an ultrahigh temperature of 2,000° C. or higher; In this case, the control system 40 controls the acceleration voltage of the DC acceleration power supply 42 and the filament current value so that the filament temperature exceeds the surface temperature of the heating chamber 11 (to be also referred to as a “heater temperature”).

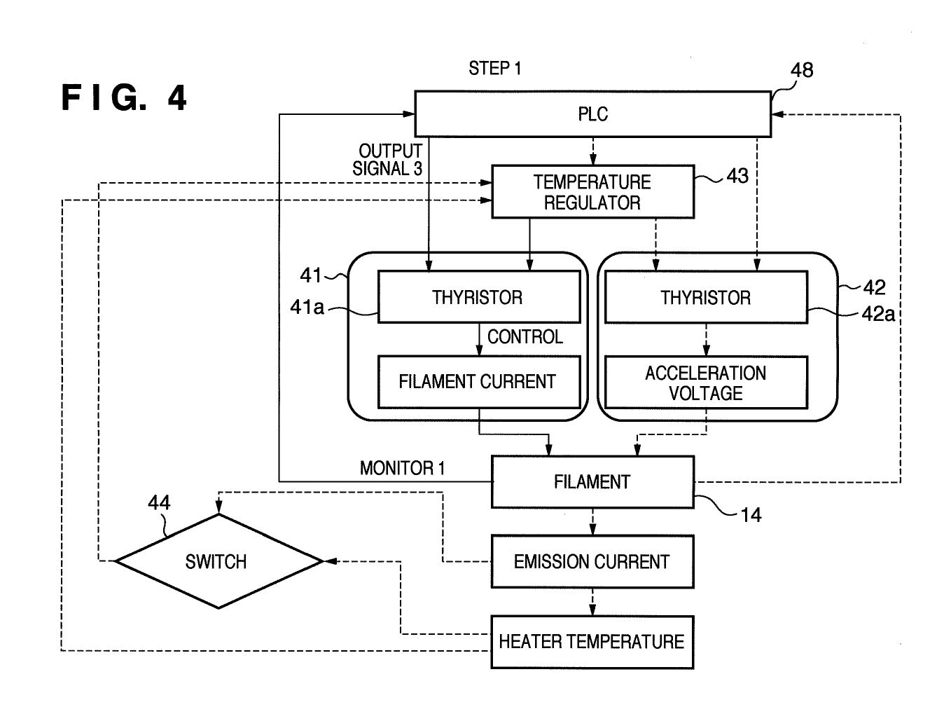

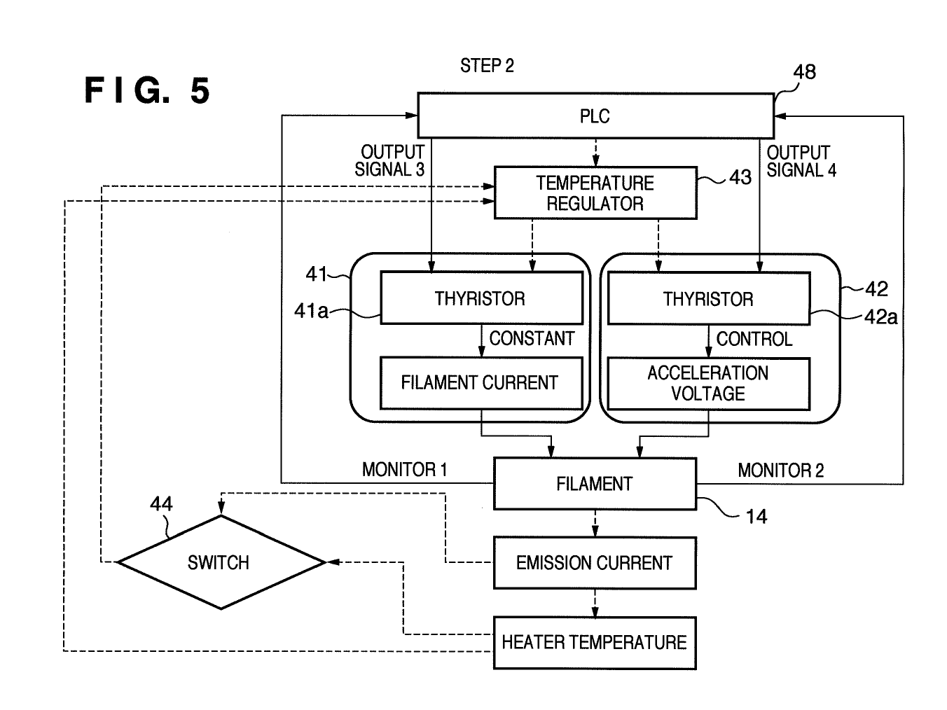

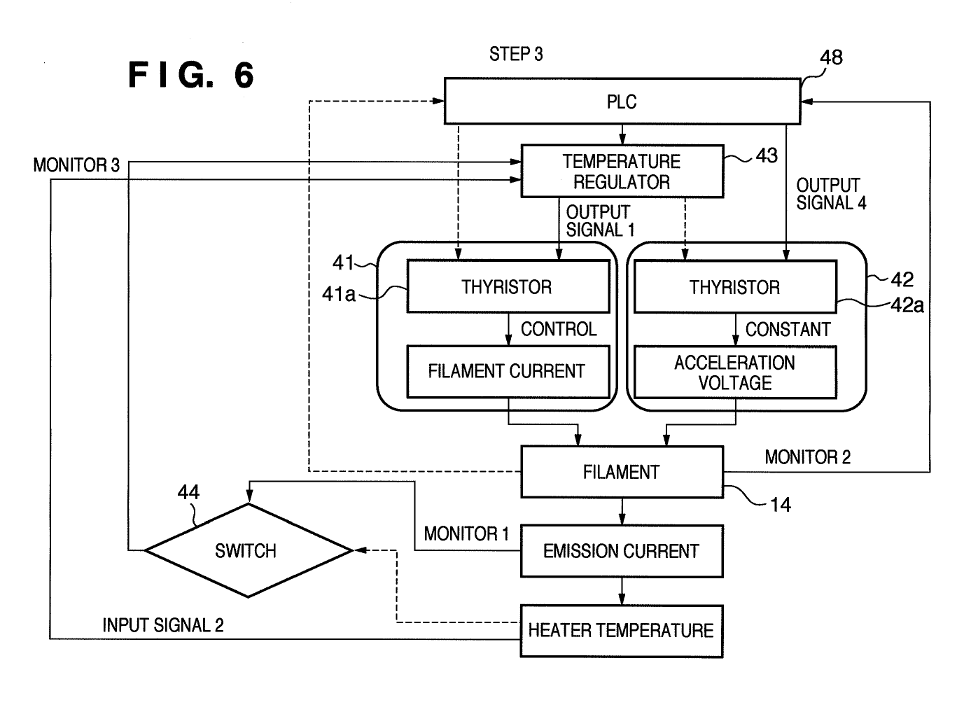

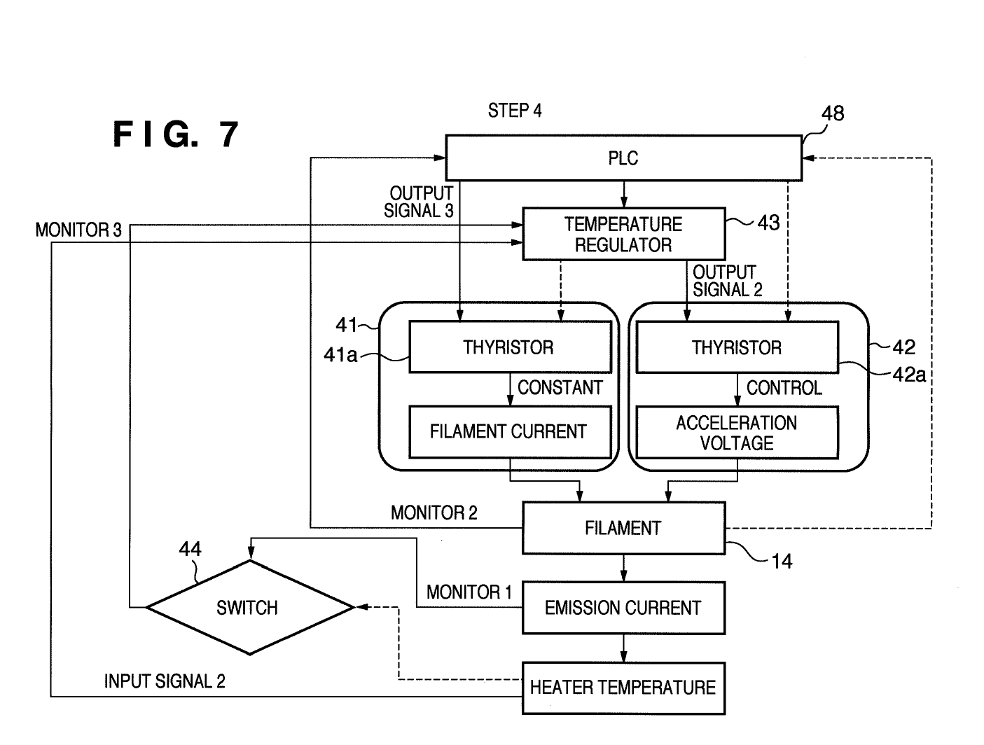

More specifically, the control system 40 performs temperature control in four steps, respectively depicted in FIGS. 4 to 7. FIG. 4 is an explanatory view showing step 1 of a temperature control sequence in the temperature control method according to the embodiment. FIG. 5 is an explanatory view showing step 2 of the temperature control sequence in the temperature control method according to the embodiment. FIG. 6 is an explanatory view showing step 3 of the temperature control sequence in the temperature control method according to the embodiment. FIG. 7 is an explanatory view showing step 4 of the temperature control sequence in the temperature control method according to the present embodiment.

The control system 40 indirectly monitors a heater temperature via the two-color radiation thermometer 7. Further, the control system 40 monitors a filament current value via the filament ammeter 45, an emission current value via the emission ammeter 47, and an acceleration voltage via the acceleration voltmeter 46.

An embodiment in which the heater is heated to obtain a heater temperature of 2,050° C. by applying the temperature control method of the present invention will be explained in detail with reference from FIGS. 4 to 7. The set values of the heater temperature, switching temperature, emission current value, acceleration voltage, and the like are arbitrarily changeable and are not limited to the embodiment.

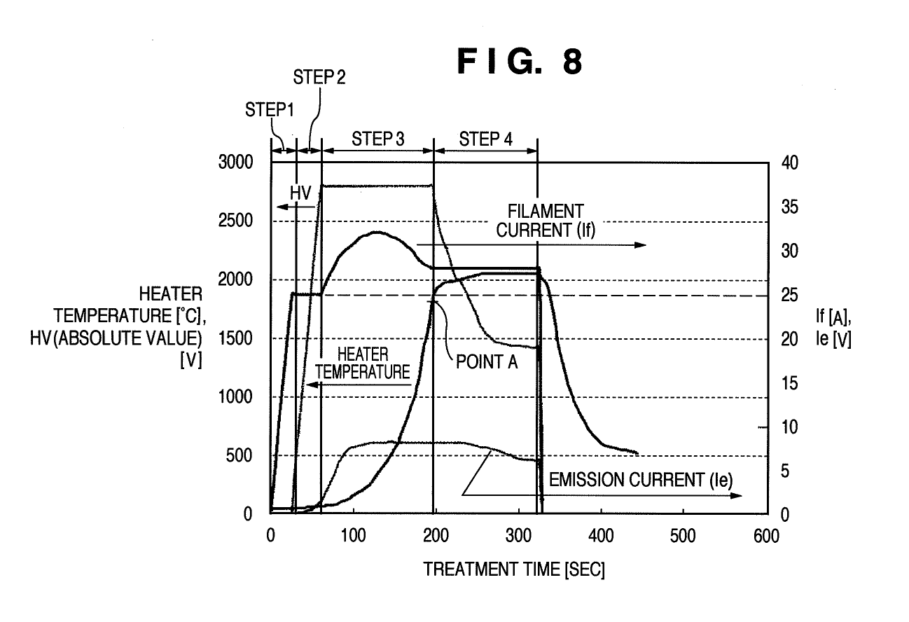

In step 1 of FIG. 4, the filament 14 is heated without applying an acceleration voltage in order to degas adsorption gas from the filament 14 and prevent an abnormal discharge. The filament current is increased by 1 ampere every 5 seconds, and after rising to 25 A, held for 5 sec. At this time, the PLC 48 directly controls to output signal 3 which is to be output to the filament 14 via the thyristor 41a of the filament power supply 41 and indicates a current value. The filament power supply 41 outputs a current having this current value via the thyristor 41a of the filament power supply 41. Step 1 described here corresponds to step 1 in FIG. 8.

In step 2 of FIG. 5, an acceleration voltage for drawing an emission current is gradually applied to prevent an abnormal discharge, similar to step 1. While the filament current value is held at 25 A, the acceleration voltage is increased by −400 V every 5 seconds, up to −2.7 kV. At this time, the PLC 48 controls to output signal 3 directly to the thyristor 41a of the filament power supply 41 so that the filament current value has a predetermined value of 25 A. The thyristor 41a of the filament power supply 41 outputs the output signal corresponding to the output signal 3, to the filament power supply, thereby outputting and controlling the filament current value. At the same time, the PLC 48 outputs output signal 4 having the acceleration voltage value directly to the thyristor 42a of the acceleration power supply 42. The acceleration power supply 42 outputs the acceleration voltage to the filament 14. Step 2 described here corresponds to step 2 in FIG. 8.

In step 3 of FIG. 6, the rate of temperature increase is increased while setting the emission current at a predetermined value of 8 A. The heater 10 is then heated quickly. At the initial stage of heating, the heater 10 is cool, so it is hard to draw emission current. The control system 40 therefore executes control to gradually increase the filament current value until the heater temperature reaches 1,750° C. (point A in FIG. 8) and the emission current value reaches 8 A. When the emission current value has reached 8 A and the heater 10 is warmed, the emission current can be easily drawn. Hence, the control system 40 executes control to maintain the emission current value at 8 A while gradually decreasing the filament current value and while the heater temperature is ramping up. The PLC 48 outputs output signal 4 to the thyristor 42a of the acceleration power supply 42 so that the acceleration voltage has a predetermined value of −2.7 kV. The thyristor 42a of the acceleration power supply 42 outputs a voltage corresponding to output signal 4 to the acceleration power supply 42, maintaining the acceleration voltage at a predetermined value of −2.7 kV.

Moreover, the switch 44 switches the control loop in the temperature regulator 43 to execute temperature control to keep the emission current constant by controlling the filament current. The PLC 48 outputs, to the temperature regulator 43, output signal having a set value at which the emission current exhibits a predetermined value of 8 A. The temperature regulator 43 compares an emission current value measured by the emission ammeter 47. The filament current value is controlled via the thyristor 41a of the filament power supply 41 so as to maintain the emission current at a desired value. The thyristor 41a of the filament power supply 41 causes the filament power supply to output a current corresponding to the above-mentioned filament current, thereby controlling the emission current value. The heater is heated by keeping the acceleration voltage constant while keeping the emission current value constant.

Step 3 here corresponds to step 3 in FIG. 8.

Note that step 3 is not indispensable for solving the technical problem of the present invention. The process may skip step 3 and shift to the following step 4 after the above-described step 2.

In step 4 of FIG. 7, when the heater temperature reaches 1,750° C. (point A in FIG. 8), the switch 44 switches the control loop in the temperature regulator 43 to execute temperature control using an acceleration voltage (emission voltage). The PLC 48 stores a filament current value at the time of switching to the temperature control. The PLC 48 directly controls the thyristor 41a of the filament power supply 41 using the stored value as output signal 3 so that the filament current has a predetermined value of 28 A. The temperature regulator 43 receives a temperature measurement value (input signal 2) from the detector 9 that has detected the heater temperature. The temperature regulator 43 compares the temperature measurement value with a heater temperature set value of 2,050° C. The temperature regulator 43 outputs output signal 2 to the thyristor 42a of the acceleration power supply 42 so that the heater temperature rises to the set value of 2,050° C. without an overshoot or undershoot. The acceleration power supply 42 outputs an acceleration voltage that realizes the set value via the thyristor 42a of the acceleration power supply 42. The acceleration voltage is controlled based on a preset PID (P: Proportional, I: Integral, D: Derivative) value. The value of a current supplied to the filament 14 in acceleration voltage control in the embodiment is 28 A. A filament temperature when the temperature finally stabilizes is calculated to be about 2,200° C. according to reference 2. Therefore, even if the heater temperature rises to 2,050° C., the filament temperature is higher than the ambient temperature including the heater 10. The thermal runaway of the emission current can be suppressed to achieve stable temperature control.

Finally, the heater is kept heated for 1 minute after the heater temperature reaches 2,050° C., and then cooled by stopping the supply of the filament current and acceleration voltage.

Step 4 corresponds to step 4 in FIG. 8.

As for a set value for keeping the filament current value constant, the temperature to which the filament itself is heated by a current flowing through the filament 14 needs to be greater than or equal to the heater temperature. In the embodiment, the filament temperature and heater temperature coincide with each other at 1,750° C. listed in Table 3 described above and indicated by point A in FIG. 8. As for the set value, it is desirable to acquire data corresponding to Table 3 in advance, obtain a temperature at which the filament temperature and heater temperature coincide with each other, and determine a filament current value corresponding to this temperature.

The algorithm of the temperature control sequence of the temperature control method is installed as, for example, a temperature control program in a storage device such as a hard disk or ROM (not shown) in the control system 40. A CPU (not shown) reads out the algorithm into the RAM and executes it.

A recording medium is of a computer-readable portable type, and the temperature control program recorded on the recording medium is installed in the storage device. The recording medium is a flash memory including a Compact Flash®, Smart Media®, Memory Stick®, multimedia card, and SD memory card. Other examples of the recording medium are a removable hard disk such as a Microdrive®, and a magnetic recording medium such as a Floppy® disk. Still other examples are a magneto-optical recording medium including an MO, and an optical disk such as a CD-R, DVD-R, DVD+R, CD-R, DVD-RAM, DVD+RW®, and Blueray.

According to the present invention, the heater temperature can be raised while always keeping the filament temperature higher than the heater temperature under the above-described control. The present invention can prevent the thermal runaway of the emission current and control the heater temperature with good reproducibility even in an ultrahigh temperature region of 2,000° C. or higher.

That is, according to this embodiment, the filament current value and acceleration voltage are controlled such that the filament temperature is always maintained so as to be higher than the surface temperature of the heating chamber 11 and such that heat is always dissipated from the filament 14 to the heating chamber 11. The heater temperature is controlled by changing the energy of thermoelectrons colliding against the heating chamber 11. In activation annealing for an ion-implanted SiC semiconductor substrate, stable temperature control can be achieved even in an ultrahigh temperature region of 2,000° C. or higher. It can be industrially implemented to electrically activate an ion-implanted impurity by 100% and completely eliminate crystal defects in the manufacture of SiC semiconductor substrates. Thereby, semiconductor devices with high reliability can be manufactured at high productivity.

### EXAMPLE

The present invention will be described in more detail by giving an example. However, the present invention is not limited to the following example.

In this example, a heater temperature control experiment was actually conducted according to the temperature control method of the present invention using the electron impact heating apparatus 1.

FIG. 8 is a graph showing a temperature profile curve when the heater temperature was held at 2,050° C. (wafer stage temperature of 1,900° C.) for 1 minute.

Activation annealing for a substrate prepared by performing ion implantation into SiC will be explained.

The treating substrate 21 was prepared by doping nitrogen as a dopant into an n-type 4H-SiC (0001) substrate having a 4° offset angle and growing an n⁺-type silicon carbide (SiC) epitaxial layer by 10 μm using a chemical vapor deposition method (CVD method).

The treating substrate 21 underwent RCA cleaning, sacrificial oxidation, and hydrofluoric acid treatment, and a passivation oxide film was grown to 10 nm for ion implantation. The resultant treating substrate 21 was used as a sample. An ion implanter capable of raising the substrate temperature heated the sample to 500° C., and implanted energy range of aluminum at 40 keV to 700 keV, an implanted concentration of 2.0×10¹⁸/cm³, and a depth of 0.8 μm at multiple steps in a box profile.

After the passivation oxide film was removed by hydrofluoric acid treatment, the electron impact heating apparatus 1 according to the present invention activated the sample. The temperature/time dependence of the activation ratio obtained by dividing the carrier concentration measured in CV measurement by the implanted concentration.

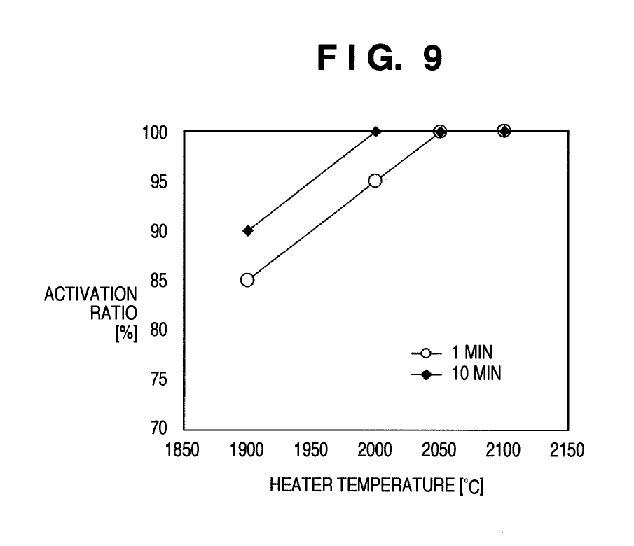

FIG. 9 is a graph showing the relationship between the activation ratio and treatment temperature of the sample. As shown in FIG. 9, it took 10 minutes for the activation ratio to reach 100% at an activation annealing temperature of 2,000° C. At an activation annealing temperature of 2,050° C., it was possible for the activation ratio to reach 100% in 1 minute.

According to the present invention, the temperature can be stably controlled even at an ultrahigh temperature exceeding 2,000° C., and annealing can be done in a short time. More specifically, an implanted impurity into silicon carbide (SiC) can be electrically activated by 100%, completely eliminating residual crystal defects. As a result, a semiconductor substrate using silicon carbide (SiC) can be fabricated with high reliability.

The preferred embodiment of the present invention has been described above. However, the embodiment is merely an example for explaining the present invention, and the scope of the present invention is not limited only to this embodiment. The present invention can be implemented in various forms different from the above embodiment without departing from the scope of the invention.

The embodiment has described annealing for a semiconductor substrate when an impurity such as Al is doped into SiC. However, the present invention is also applicable to annealing for a semiconductor substrate containing another impurity.

The present invention is not limited to the above embodiment and various changes and modifications can be made within the spirit and scope of the present invention. Therefore, to apprise the public of the scope of the present invention the following claims are made.

This application claims the benefit of Japanese Patent Application Nos. 2009-078192 filed Mar. 27, 2009 and 2010-048233 filed Mar. 4, 2010, which are hereby incorporated by reference herein in their entireties.

What is claimed is:

1. A temperature control method for a heating apparatus including a chamber which can be evacuated and has a conductive portion, a filament which is positioned in the chamber, a first power supply which supplies a current to the filament, a second power supply which applies, to the filament, a voltage for acceleration to the chamber, an ammeter which measures a current of the filament, and a voltmeter which measures the acceleration voltage, the method comprising:
a first step of evacuating an interior of the chamber;
a second step of supplying the filament current from the first power supply to the filament after the first step;
a third step of applying the acceleration voltage to the filament after the second step; and
a fourth step of controlling the acceleration voltage to keep a surface temperature of the chamber to be lower than a temperature of the filament after the third step while keeping constant the filament current from the first power supply.

2. The method according to claim 1, further comprising a fifth step of controlling the filament current from the first power supply to keep constant an emission current flowing through a path between the filament and the chamber after the third step and before the fourth step while keeping constant the acceleration voltage from the second power supply.

3. The method according to claim 1, wherein the chamber is formed from a graphite base and an outer surface coated with one of pyrolitic carbon and tantalum carbide.

4. The method according to claim 1, further comprising a heater arranged in the chamber, and
the surface temperature of the chamber is measured by one of direct measurement of a temperature of the heater, and indirect measurement of one of a temperature of a substrate arranged to face the heater and a temperature of a substrate stage which supports the substrate.

5. A computer-readable storage medium storing a computer-executable program, said program being executable by a computer so as to control the computer of the heating apparatus to execute the temperature control method according to claim 1.
